(19) United States
(12) Patent Application Publication
(10) Pub. No.: US 2022/0231176 A1
(43) Pub. Date: Jul. 21, 2022

(54) ZERO-BIAS PHOTOGATE PHOTODETECTOR

(71) Applicant: Omid Habibpour, Göteborg (SE)

(72) Inventor: Omid Habibpour, Göteborg (SE)

(21) Appl. No.: 17/421,456

(22) PCT Filed: Jul. 7, 2020
(86) PCT No.: PCT/SE2020/050716

§ 371 Date: Jul. 8, 2021

(30) Foreign Application Priority Data
Sep. 21, 2019 (SE) 1930298-3

(51) Int. Cl. H01L 31/0224; H01L 31/112

(52) U.S. Cl. CPC H01L 31/0224; H01L 31/112

(57) ABSTRACT

A photogate photodetector (10) comprising: a first electrode consisting of amorphous germanium (12) covered with transition metal species having a thickness in the range of 0.1-5 nm (11); a second electrode (14) which is an n-type silicon layer; and a dielectric layer (13) arranged between the first and second electrode; with a depletion layer (15) formed in the n-type silicon layer (14) at the interface to the dielectric layer (13).

### FIELD OF THE INVENTION

The present invention relates to a zero-bias photogate photodetector based on silicon. In particular, the invention significantly reduces leakage currents and increases sensitivity.

### BACKGROUND OF THE INVENTION

A photogate detector is a metal-oxide-semiconductor (MOS) capacitor with polysilicon as the top terminal called gate. A DC voltage is applied to the gate to form a depletion layer consisting of ionized dopants near the surface under the gate. In the depletion layer, an electric filed is created allowing to separate electron-hole pairs generated by the absorbed photons. This type of photodetectors transduces optical signals into stored charges rather than voltage or current signals. The stored charges can be converted to voltage or current signals with appropriate additional circuits.

By applying a pulsed light signal rather than a continuous signal, we can charge and discharge the photogate and generate electric currents which is equal to the rate of change of charge in the photogate. The peak of the generated current is proportional to the amplitude of the light pulse. Hence, operation in the pulsed mode eliminates the need for the additional circuit for converting the storage charge to current or voltage signals. In addition, the detector become insensitive to the background radiation. However, the applied gate voltage required for the formation of the depletion layer generates leakage currents that limits the sensitivity of such detectors.

### SUMMARY

In order to alleviate above-mentioned and other drawbacks of the prior art, it is an object of the present invention to provide an improved photogate photodetector with ultralow dark currents.

According to the first aspect of the invention, there is provided a zero-bias photogate photodetector comprising: a first electrode consisting of amorphous germanium covered with a few atomic layers of transition metal species; a second electrode which is an n-type silicon; a dielectric layer arranged between the first and second electrode.

The described photodetector is based on the experiment showing that amorphous germanium covered with a few atomic layers of transition metals behaves like negative point-charges that can repel electrons in the n-type silicon and create a depletion layer in the n-type silicon at the interface to the dielectric layer. The electron-hole pairs generated by the absorbed photons in the depletion layer are separated and stored under the gate. Hence a pulsed light signal can charge and discharge the photogate and in turn giving rise to a current through the device for a closed circuit. The measured current is correlated to the amplitude of the light pulse and determines the amount of light intensity.

The present invention is thus based on the realization of a photogate photodetector without any gate-bias voltage (zero-bias). This significantly reduces leakage current and increase the detector sensitivity. It has been found that an example embodiment of the described photodetector has a leakage current in the range of a few picoamp per cm² meaning that it can detect ultra-weak radiation.

According to one embodiment of the invention, transition metal species used to form thin metal layer are preferably selected from the group of Ni, Cr, Nb, Mo, Au, Pt, Fe, Cu, Ta, V, Co and W. Accordingly, it is possible to form a metal alloy comprising two or more metals.

According to one embodiment of the invention, a thickness of the metal layer may be in the range of 0.1 nm to 5 nm. The metal thickness depends on the choice of material and it should be thin enough to make separate islands to replica point charges.

According to one embodiment of the invention, a thickness of the amorphous germanium may be in the range of 5 nm to 200 nm. The amorphous germanium thickness should be thick enough to have a continuous thin film. In addition, it should not be too thick to block the incident photons to reach to the depletion region.

According to one embodiment of the invention, a thickness of the dielectric layer may be in the range of 5 nm to 100 nm. The thickness of the dielectric layer should be enough to electrically insulate the first electrode from the second electrode, and the thickness depends on the choice of material. The dielectric layer may for example consist of Al2O3, SiO2, Hf2O, HfSiO, HfSiON, SiN or AlN.

Further advantages and advantageous features of the present invention will become apparent when studying the following description and the dependent claims.

### BRIEF DESCRIPTION OF THE DRAWINGS

With reference to the appended drawing showing an example embodiment of the present invention, below follows a more detailed description of the various aspect of the invention.

FIG. 1 schematically illustrates a zero-bias photogate-photodetector according to an embodiment of the invention.

### DETAILED DESCRIPTION OF EXAMPLE EMBODIMENTS

The present invention will now be described more afterward in this document with reference to the accompanying drawing.

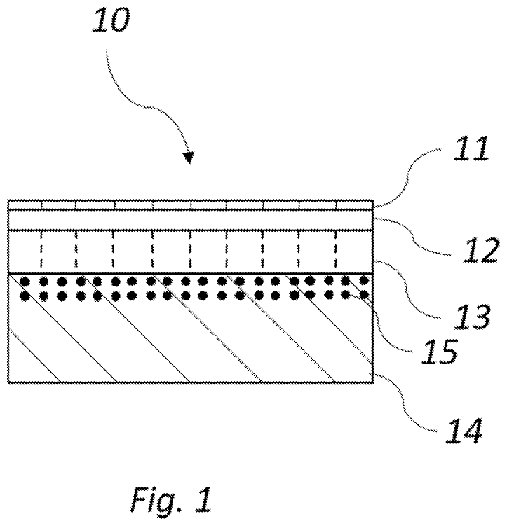

FIG. 1 schematically shows a zero-bias photogate photodetector 10 comprising: a first electrode consisting of amorphous germanium 12 covered with a few atomic layers of transition metal species 11; a second electrode 14 which is an n-type silicon; a dielectric layer 13 arranged between the first and second electrode. A depletion layer 15 is formed in the n-type silicon layer 14 at the interface to the dielectric layer 13.

The material used to form thin metal layer 11 are selected from transition metal Ni, Cr, Nb, Mo, Au, Pt, Fe, Cu, Ta, V, Co and W. Accordingly, it is possible to forma metal alloy comprising two or more metals.

The amorphous germanium 12 may have a thickness in the range of 5-200 nm, the dielectric 13 may have a thickness in the range of 5-100 nm and the thin metal layer 11 may have a thickness in the range of 0.1-5 nm.

1. A photogate photodetector (10) comprising:
a first electrode consisting of amorphous germanium (12) covered with transition metal species having a thickness in the range of 0.1-5 nm (11);
a second electrode (14) which is an n-type silicon layer; and
a dielectric layer (13) arranged between the first and second electrode; with
a depletion layer (15) formed in the n-type silicon layer (14) at the interface to the dielectric layer (13).

2. The photogate photodetector according to claim 1, wherein the metal specie is selected from Ni, Cr, Nb, Mo, Au, Pt, Fe, Cu, Ta, V, Co and W.

3. The photogate photodetector according to claim 1, wherein the metal specie consists of a metal alloy, wherein the metal alloy comprises at least two of Ni, Cr, Nb, Mo, Au, Pt, Fe, Cu, Ta, V, Co and W.

4. The photogate photodetector according to any one of the preceding claims, wherein a thickness of the amorphous germanium layer is in the range of 5 nm to 200 nm.

5. The photogate photodetector according to any one of the preceding claims, wherein a thickness of the dielectric layer is in the range of 5 nm to 100 nm.

6. The photogate photodetector according to any one of the preceding claims, wherein the dielectric layer is selected from Al2O3, SiO2, Hf2O, HfSiO, HfSiON, SiN or AlN.

7. The photogate photodetector according to any one of the preceding claims, wherein the dielectric layer comprises at least two of Al2O3, SiO2, Hf2O, HfSiO, HfSiON, SiN or AlN.
